(19) United States
(12) Patent Application Publication
(10) Pub. No.: US 2005/0287796 A1
(43) Pub. Date: Dec. 29, 2005

(54) Methods of fabricating metal lines in semiconductor devices

(76) Inventor: Sang Woo Nam, Cheongju-si (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/027,517

(22) Filed: Dec. 30, 2004

(30) Foreign Application Priority Data
Jun. 24, 2004 (KR) 2004-47525

(51) Int. Cl. H01L 21/4763; H01L 21/302

(52) U.S. Cl. 438/638; 438/710; 438/637; 438/712

(57) ABSTRACT

Methods to form metal lines in semiconductor devices are disclosed. An illustrated method comprises: depositing first and second interlayer dielectric layers on a semiconductor substrate; forming a via hole in the second interlayer dielectric; forming a photoresist pattern, forming a trench, using the photoresist pattern as a mask; removing an portion of the first interlayer dielectric layer that is exposed through the trench; and filling metal in the via hole and the trench to form the metal line. Etching the second interlayer dielectric layer, removing the photoresist pattern; and removing the exposed portion of the first interlayer dielectric layer are performed in-situ in the same chamber.

### FIELD OF THE DISCLOSURE

The present disclosure relates generally to metallization technologies, and more particularly to methods of forming metal lines in semiconductor devices.

### BACKGROUND

As the integration of semiconductor IC devices increases, the metal lines formed within the IC devices must be made narrower and multilayered. The decrease in the width of the metal lines produces signal delay due to the increase of the electrical resistance and capacitance of the metal lines. To reduce this signal delay, copper metal having low resistance has been widely used for the metal lines.

The electrical resistance of copper is 62% of the electrical resistance of aluminum. Copper also has superior resistance against electromigration, which improves the reliability of copper metallization in highly integrated and/or high speed devices. Because copper is not dry-etched differently from aluminum, a damascene process has been developed wherein a trench is formed in a semiconductor substrate, a metal film is deposited in the trench, and the metal film is polished by a CMP (Chemical Mechanical Polishing) process.

FIGS. 1a and 1b are cross sectional views illustrating a conventional method for forming a damascene structure. Referring to FIG. 1a, a nitride film 12 and an interlayer dielectric 14 are formed on a semiconductor substrate 10. The interlayer dielectric 14 is etched by a selective etching process using a photoresist mask to form a via (V). Then, a trench (T) is formed by a selective etching process using a photoresist (PR) mask.

Referring to FIG. 1b, the photoresist (PR) is removed. The nitride film 12 exposed through the via (V) is removed by a selective etching process. Next, a copper metal line 16 is formed by filling the trench with copper metal.

However, in the conventional structure manufactured by the above method, various ones of the processes for forming the copper metal lines (i.e., forming the trench, removing the photoresist and nitride, and forming the via) must be performed in different etching apparatus and different chambers, which complicates the fabrication process and decreases productivity due by increasing processing time.

### BRIEF DESCRIPTION OF THE DRAWINGS

FIGS. 1A and 1B are cross sectional views illustrating a conventional prior art method for forming metal lines in a semiconductor device.

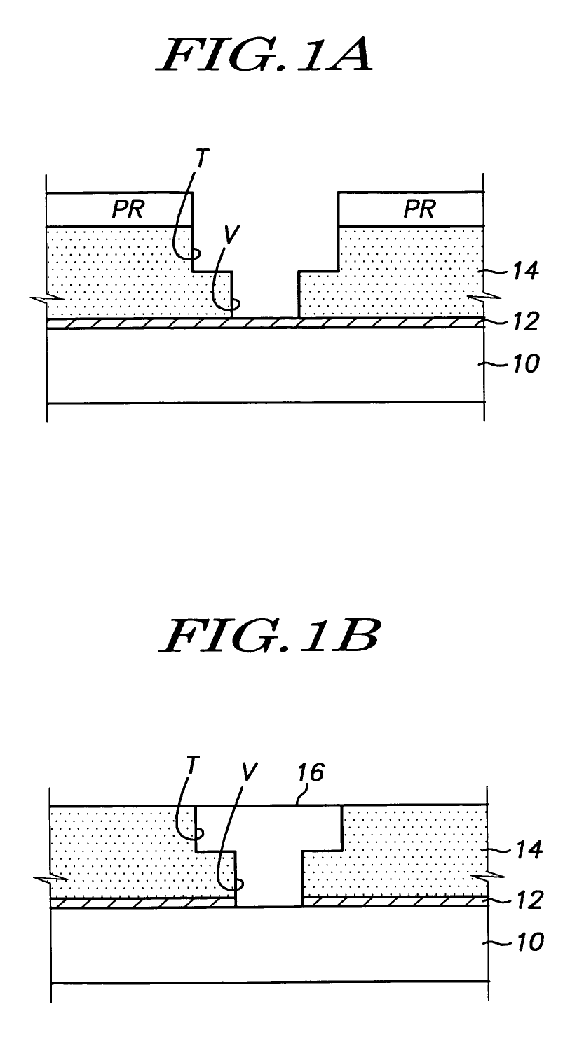

FIG. 2 is a cross sectional view of an example semiconductor device constructed in accordance with the teachings of the present invention.

FIGS. 3A to 3C are cross sectional views illustrating an method for forming copper metal line performed in accordance with the teachings of the present invention.

FIG. 4 is a schematic diagram of an example plasma etching apparatus for manufacturing semiconductor IC devices.

### DETAILED DESCRIPTION

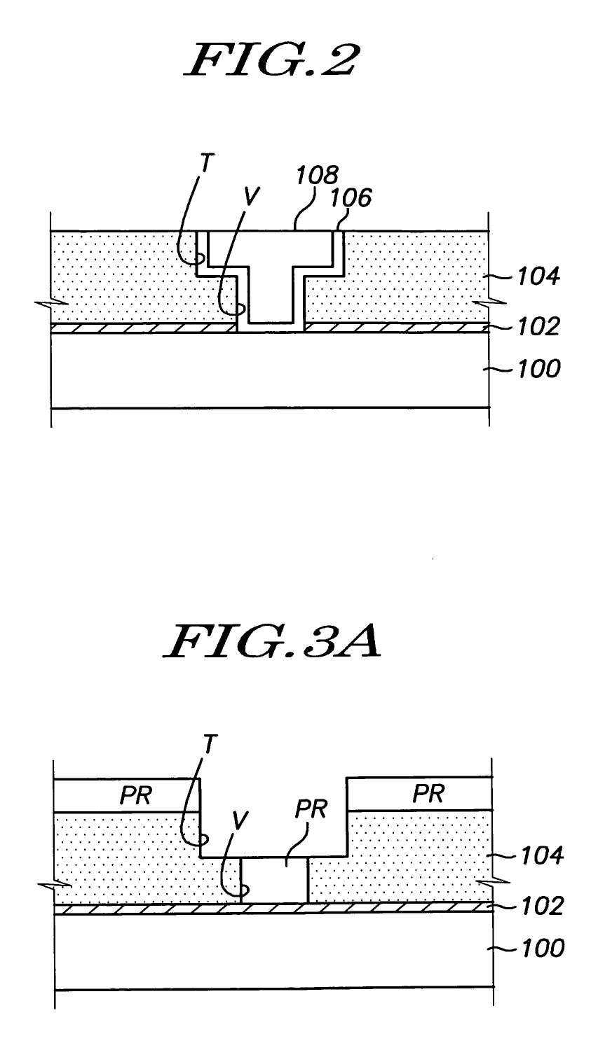

FIG. 2 is a cross sectional view illustrating an example copper metal line constructed in accordance with the teachings of the present invention. Referring to FIG. 2, first and second interlayer dielectrics 102 and 104 are formed on a semiconductor substrate 100. The semiconductor substrate 100 may be, for example, a silicon substrate. In the illustrated example, the first interlayer dielectric 102 is made of, for example, silicon nitride (SiN) to protect the metal line. In the illustrated example, the metal line is made of copper. In the illustrated example, the second interlayer dielectric 104 is preferably made of FSG (Fluorine Silicate Glass).

A trench (T) is formed in the second interlayer dielectric 104. A via hole (V) is formed through the first interlayer dielectric 102 and the second interlayer dielectric 104. The via (V) is in communication with the trench (T). In the illustrated example, the trench (T) and via hole (V) are filled with copper to form metal line 108 which may be electrically interconnected to other metal wiring or circuit components. (Layer 106 is a metal barrier layer to prevent diffusion of copper into the dielectric 104.)

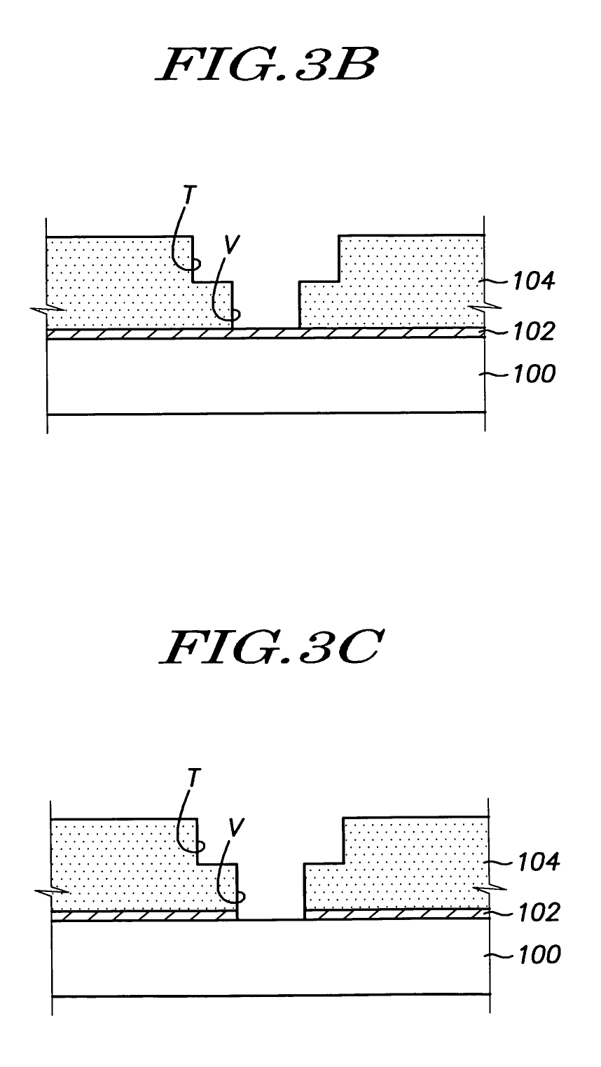

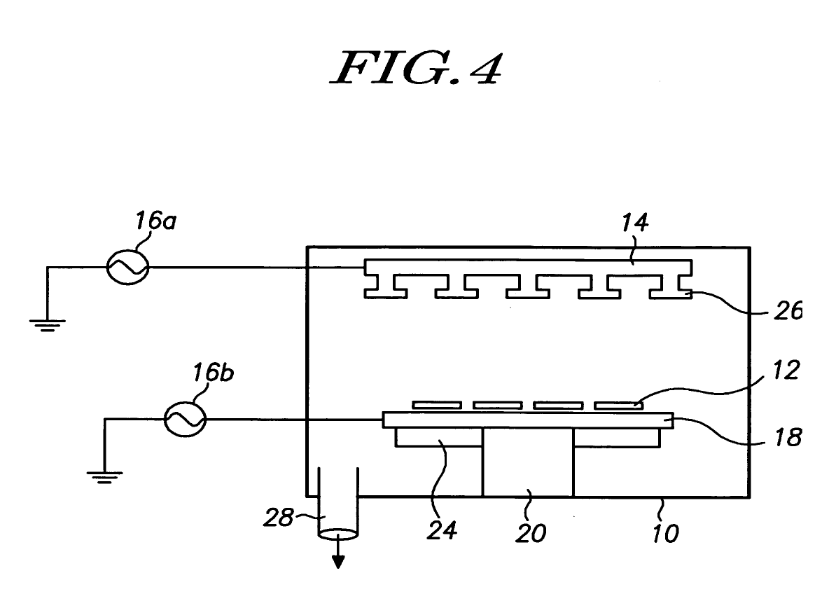

An example manufacturing method for forming metal lines will now be explained with reference to FIGS. 3A to 3C and FIG. 4. FIGS. 3A to 3C are cross sectional views illustrating an example method for forming metal lines in semiconductor IC devices performed in accordance with the teachings of the present invention. FIG. 4 is a schematic diagram of an example plasma etching apparatus suitable for use in performing the example method of FIGS. 3A to 3C.

Referring first to FIG. 4, the example plasma etching apparatus of the illustrated example includes a chamber 10 that provides a reaction space where thin films are deposited by reaction gases. The reaction space within the chamber 10 is isolated from the outside.

In the example of FIG. 4, a first electrode 14 is formed in the upper part of the chamber 10. The electrode 14 of the illustrated example is made of metal (e.g., aluminum) and provides RF (Radio Frequency) power for evenly spreading the reaction gas on the top surface of a wafer 100. The first electrode 14 is connected to a first RF power generator 16a.

In the example of FIG. 4, a second electrode 18 is formed in the lower part of the chamber 10 opposite the first electrode 14. The second electrode 18, which is connected to a second RF power generator 16b, is formed of metal (e.g., aluminum) and generates plasma. The first and second RF power generators 16a and 16b can be made in one body.

In the illustrated example, the second electrode 18 is movable up and down by a transporting motor 20. In the example of FIG. 4, a heater 24 that applies heat to the substrate 12 is disposed at the lower side of the second electrode 18. The heater 24 may be a high-intensity lamp or a resistor heater.

In the illustrated example, a shower head 26 for introducing reaction gas into the chamber 10 is connected to the upper side of the chamber 10. An outlet 28 for exhausting reaction gas from the chamber 10 is connected to the lower side of the chamber 10. The shower head 26 may have a number of holes for delivering reaction gas into the inside of the chamber 10, and/or may be integrally formed (i.e., formed as one body) with the first electrode 14. In the illustrated example, gases introduced into the chamber 10 through the shower head 26 are sufficiently mixed and diffused to evenly spread to the top surface of the substrate 12. Next, the gas is exhausted to the outside through the outlet 28.

An example method for forming a metal film using the above-described plasma etching apparatus will now be explained. Referring FIG. 3A, first and second interlayer dielectric layers 102 and 104 are sequentially deposited on the substrate 100 on which metal wirings are to be formed.

In the illustrated example, the first interlayer dielectric 102 is formed of silicon nitride (SiN), which acts as an etch stop layer during a via hole etching in subsequent dual damascene processes. Also, in the example shown in FIG. 3A, the second interlayer dielectric 104 is made of FSG (Fluorine Silicate Glass).

Next, a via hole (V) is formed in the second interlayer dielectric 104 by selectively etching using a photo mask. Photoresist is then deposited on the overall surface of the substrate 100 in which the via hole (V) is formed. The photoresist is then developed to form a photoresist pattern (PR) that exposes an area of the second interlayer dielectric 104 for a trench for forming the metal lines. In the example of FIG. 3A, the via hole (V) is filled with the photoresist and prevents the underlying thin film from being etched in a subsequent etching process.

The exposed area of the second interlayer dielectric 104 is etched while using the photoresist pattern (PR) as a mask to form a trench (T) that is interconnected with the via hole (V). In the illustrated example, the etching of the second interlayer dielectric 104 is performed using the equipment of FIG. 4 and under conditions wherein the chamber pressure is about 120˜180 mT, the RF power supply connected to the first electrode delivers about 320˜480 W at a frequency of about1.6˜2.4 MHz, the RF power supply connected to the second electrode delivers about 320˜480 W at a frequency of about 21.6˜28.4 MHz, and using etchant gases of Ar of about 160˜240 sccm, CF₄ of about 40˜60 sccm, O₂ of about 7.2˜10.8 sccm and CHF₃ of about 20˜30 sccm at a temperature ranging from about 16° C. to about 24° C. for about 40˜60 seconds.

Referring to FIG. 3B, the photoresist pattern (PR) is removed. The removal of the photoresist pattern (PR) is performed in the illustrated example by an in-situ process and under conditions wherein the chamber pressure is about 248˜372 mT, the RF power supply connected to the first electrode delivers about −20˜20 W at a frequency about 1.6˜2.4 MHz, the RF power supply connected to the second electrode delivers about 340˜360 W at a frequency about 21.6˜28.4 MHz, and wherein O₂ etchant gas is introduced at about 1,520˜2,280 sccm at a temperature ranging from about 16° C. to about 24° C. for about 40˜80 seconds.

Referring to FIG. 3C, the first interlayer dielectric 102 exposed by the via hole (V) is removed. The removal of the first interlayer dielectric 102 is performed in an in-situ process under conditions wherein the chamber pressure is about 80˜120 mT, the RF power supply connected to the first electrode delivers about 80˜120 W at a frequency about 1.6˜2.4 MHz, the RF power supply connected to the second electrode delivers about 340˜360 W at a frequency of about 21.6˜28.4 MHz, and wherein Ar etchant gas is introduced at about 360˜540 sccm, CF₄ etchant gas is introduced at about 5.6˜8.4 sccm, CHF₃ etchant gas is introduced at about 11.2˜16.8 sccm and O₂ etchant gas is introduced at about 6.4˜9.6 sccm at a temperature ranging from about 16° C. to 24° C. for about 24˜36 seconds.

As shown in FIG. 2, a barrier metal layer 106 is formed along the inner walls of the trench (T) and via hole (V) formed in the substrate 100. Then, copper metal is deposited to fill the space defined by the barrier metal layer 106 in the trench (T) and the via hole (V). The copper is then polished by a CMP process until the second interlayer dielectric 104 is exposed to form a copper metal line 108.

By adjusting the conditions in the chamber 10 as explained above, it is possible to form the via hole (V) and the trench (T) in an in-situ process, thereby simplifying the fabrication process. Further, damage due to particles in the successive processes is decreased. Moreover, the fabrication process is performed at a lower temperature (about 20° C.) and, thus, it is possible to improve the contact reliability and prevent the formation of oxide film that may otherwise occur on the copper metal region exposed by the via hole at higher processing temperatures.

From the foregoing, persons of ordinary skill in the art will appreciate that methods have been disclosed which can simplify forming metal lines in semiconductor IC devices. Such persons will further appreciate that the disclosed methods improve the productivity of semiconductor IC devices.

In an illustrated method, trenches are formed in one chamber by varying processing conditions. More specifically, an illustrated method for forming a metal line in a semiconductor IC device comprises: depositing first and second interlayer dielectric layers on a semiconductor substrate; forming a via hole in the second interlayer dielectric; depositing photoresist on the overall surface of the substrate, exposing and developing the deposited photoresist to form a photoresist pattern; forming the trench in an in-situ process while using the photoresist pattern as a mask, removing a portion of the first dielectric layer exposed by the trench and via hole; and filling metal in the via hole and the trench to form the metal line.

In a disclosed example, the trench is formed under conditions wherein the chamber pressure is about 120˜180 mT, the RF power connected to the first electrode is about 320˜480 W at about 1.6˜2.4 MHz, the RF power connected to the second electrode is about 320˜480 W at about 21.6˜28.4 MHz, and the etchant gases employed are Ar at about 160˜240 sccm, CF₄ at about 40˜60 sccm, O₂ at about 7.2˜10.8 sccm and CHF₃ at about 20˜30 sccm at a temperature ranging from about 16° C. to about 24° C. for about 40˜60 seconds. The photoresist pattern is removed under conditions wherein the chamber pressure is about 248˜372 mT, the RF power connected to the first electrode is about −20˜20 W at a frequency about 1.6˜2.4 MHz, the RF power connected to the second electrode is about 340˜360 W at a frequency of about 21.6˜28.4 MHz, and the etchant gas employed is O₂ at about 1,520˜2,280 sccm at a temperature ranging from about 16° C. to about 24° C. for about 40˜80 seconds. Further, the exposed portion of the first interlayer dielectric is removed under conditions wherein the chamber pressure is about 80˜120 mT, the RF power connected to the first electrode is about 80˜120 W at a frequency of about 1.6˜2.4 MHz, the RF power connected to the second electrode is about 340˜360 W at a frequency of about 21.6˜28.4 MHz, and wherein the etchant gases introduced into the chamber are Ar at about 360˜540 sccm, CF₄ at about 5.6˜8.4 sccm, CHF₃ at about 11.2˜16.8 sccm and O₂ at about 6.4˜9.6 sccm at a temperature ranging from about 16° C. to about 24° C. for about 24˜36 seconds.

It is noted that this patent claims priority from Korean Patent Application Serial Number 10-2004-47525, which was filed on Jun. 24, 2004, and is hereby incorporated by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. A method for forming a metal line in a semiconductor device comprising:
depositing first and second interlayer dielectric layers on a semiconductor substrate;
forming a via hole in the second interlayer dielectric;
forming a photoresist pattern;
etching the second interlayer dielectric layer while using the photoresist pattern as a mask to form a trench;
removing the photoresist pattern;
removing a portion of the first interlayer dielectric layer exposed through the trench; and
filling metal in the via hole and the trench to form the metal line, wherein etching the second interlayer dielectric layer, removing the photoresist pattern; and removing the exposed portion of the first interlayer dielectric layer are performed in-situ in a chamber.

2. A method as defined in claim 1, wherein etching the second interlayer dielectric layer is performed with a chamber pressure at about 120˜180 mT, RF power connected to a first electrode within the chamber at about 320˜480 W at a frequency of about 1.6˜2.4 MHz, RF power connected to a second electrode within the chamber at about 320˜480 W at a frequency of about 21.6˜28.4 MHz, and while introducing Ar at about 160˜240 sccm, CF₄ at about 40˜60 sccm, O₂ at about 7.2˜10.8 sccm and CHF₃ at about 20˜30 sccm at a temperature of about 16° C. to about 24° C. for about 40˜60 seconds.

3. A method as defined in claim 1, wherein removing the photoresist pattern is performed with a chamber pressure of about 248˜372 mT, RF power connected to a first electrode within the chamber at about −20˜20 W at a frequency of about 1.6˜2.4 MHz, RF power connected to a second electrode within the chamber at about 340˜360 W at a frequency of about 21.6˜28.4 MHz, and while introducing O₂ at about 1,520˜2,280 sccm at a temperature of about 16° C. to about 24° C. for about 40˜80 seconds.

4. A method as defined in claim 1, wherein removing the portion of the first interlayer dielectric is performed with a chamber pressure of about 80˜120 mT, RF power connected to a first electrode within the chamber at about 80˜120 W at a frequency of about 1.6˜2.4 MHz, RF power connected to the second electrode within the chamber at about 340˜360 W at a frequency of about 21.6˜28.4 MHz, and while introducing Ar at about 360˜540 sccm, CF₄ at about 5.6˜8.4 sccm, CHF₃ at about 11.2˜16.8 sccm and O₂ at about 6.4˜9.6 sccm at a temperature ranging from about 16° C. to about 24° C. for about 24˜36 seconds.
